(19) United States
(12) Patent Application Publication
(10) Pub. No.: US 2015/0293169 A1
(43) Pub. Date: Oct. 15, 2015

(54) METHOD, SYSTEMS, AND DEVICES FOR INSPECTING SEMICONDUCTOR DEVICES

(71) Applicant: MACRONIX INTERNATIONAL CO., LTD., Hsinchu (TW)

(72) Inventors: Yen Chuang, New Taipei City (TW); Che-Lun Hung, Hsinchu County (TW)

(73) Assignee: MACRONIX INTERNATIONAL CO., LTD., Hsinchu (TW)

(21) Appl. No.: 14/252,583

(22) Filed: Apr. 14, 2014

(51) Int. Cl. G01R 31/265

(52) U.S. Cl. CPC G01R 31/2653; G01R 31/2656

(57) ABSTRACT

Present example embodiments relate generally to methods, logic, systems, and devices for inspecting a semiconductor device. Example methods comprise applying an initial energy from an energy source to a first location of a conductive layer of the semiconductor device. Example methods further comprise measuring a resultant energy passing through the conductive layer using a probe at a second location of the conductive layer and analyzing the measured resultant energy passing through the conductive layer. Example methods further comprise determining a presence of an inconsistency in the conductive layer based on the analyzing.

### BACKGROUND

The present disclosure relates generally to semiconductor structures and/or devices, fabricating semiconductor structures and/or devices, and more specifically, relates to inspecting fabricated and/or partially fabricated semiconductor structures and/or devices.

In the continuously evolving semiconductor field, semiconductor manufacturers generally compete to bring to market semiconductor devices, such as memory devices, having both greater storage capacity and smaller physical size. Semiconductor device manufacturers attempt to achieve one or more of these goals by making dimensionally smaller each of the patterns in the series of patterns formed on photoresist masks, photoresist layers, and corresponding fabricated semiconductor structures and devices. Alternatively or in addition, attempts include forming the patterns on the mask, the photoresist layers, and corresponding fabricated semiconductor structures and devices to be dimensionally closer to one another so as to increase the density of patterns formed on the resultant semiconductor device.

Semiconductor devices are generally fabricated by performing a photolithography process, wherein a mask is subjected to an exposure to light and a series of patterns are formed on portions of a photoresist layer exposed to the light. The series of patterns formed on the photoresist layer, along with one or more underlying layers between the photoresist layer and its corresponding substrate, are then etched to form patterns. These patterns can be visualized as elongated trenches surrounded or isolated by insulative walls (such as oxide layers). Thereafter, one or more conductive layers are formed in the etched patterns, forming electrical interconnects. Traditionally, the aforementioned one or more conductive layers were formed using conductive metals such as aluminum, or the like. More recently, conductive layers have been formed using a damascene process, dual damascene process, or the like, in which traditional metals such as aluminum, or the like, have become replaced with copper, or the like, so as to improve performance (such as lower resistivity), reduction in size (such as higher current densities), and increased reliability (such as lower activation energy, higher thermal conductivity, and more resistivity to electromigration failures).

### BRIEF SUMMARY

With the recent developments described above, including shrinking of critical dimensions of semiconductor devices and those described above, and forming electrical interconnects using a damascene process, dual damascene process, or the like, it is recognized in the present disclosure that one or more problems are encountered in the fabrication of semiconductor structures and devices, including difficulties in achieving improved performance and increased reliability resulting from, among other things, defects arising on and in the conductive layer (electrical interconnects) of the semiconductor structures and devices. Such defects include surface defects, pits, oxide bridges, partial breaks, and complete or total breaks (openings) in the conductive layer.

Present example embodiments relate generally to methods, logic, systems, and devices for inspecting (or examining or testing) fabricated and/or partially fabricated semiconductor structures and/or devices, including determining whether or not one or more conductive layers of the semiconductor structures and/or devices comprise inconsistencies, including defects, within a conductive layer and/or at the conductor/oxide borders of the conductive layer (generally and without limitation referred to for convenience herein as “internal defects”) and/or surface inconsistencies and/or defects. Present example embodiments are further directed to identifying the severity of the internal defects, including determining whether the internal defects include pits, partial breaks, and/or complete breaks. Present example embodiments are further directed to locating an approximate location of the internal defects within the conductive layer of fabricated and/or partially fabricated semiconductor structures and/or devices.

In an example embodiment, a method for inspecting a semiconductor device comprises applying an initial energy from an energy source to a first location of a conductive layer of the semiconductor device. The method further comprises measuring a resultant energy passing through the conductive layer using a probe at a second location of the conductive layer and analyzing the measured resultant energy passing through the conductive layer. The method further comprises determining a presence of an inconsistency in the conductive layer based on the analyzing.

In another example embodiment, a system for inspecting a semiconductor device comprises an energy source operable to apply an initial energy to a first location of a conductive layer of the semiconductor device. The system further comprises a probe operable to measure a resultant energy passing through the conductive layer at a second location of the conductive layer. The system further comprises a processor operable to analyze the measured resultant energy passing through the conductive layer. The processor is further operable to determine a presence of an inconsistency in the conductive layer based on the analyzing.

### BRIEF DESCRIPTION OF THE DRAWINGS

For a more complete understanding of the present disclosure, example embodiments, and their advantages, reference is now made to the following description taken in conjunction with the accompanying drawings, in which like reference numbers indicate like features, and:

FIG. 1A is a cross-sectional view of a semiconductor structure and/or device having internal defects and surface defects, the semiconductor structure and/or device being inspected using conventional methods and tools;

FIG. 1B is a top view of a semiconductor structure and/or device;

FIG. 2 is an example embodiment of a method of inspecting a semiconductor device;

FIG. 3 is an example embodiment of a method of analyzing the measured resulting energy and determining a presence of an inconsistency in the conductive layer of a semiconductor device;

FIG. 4 is an example embodiment of a method of identifying a severity of an inconsistency in the conductive layer of a semiconductor device;

FIG. 5 is an example embodiment of a method of identifying a approximate location of an inconsistency in the conductive layer of a semiconductor device;

FIG. 6 is a top view of an example embodiment of a system for inspecting a semiconductor device, which merely illustrates inconsistencies within the conductive layer that are not visible and not detectable using conventional methods and tools, but may be detected, identified, and located using example embodiments;

FIG. 7A is a cross-sectional view of an example semiconductor device fabricated using a damascene process that may be inspected using example embodiments described in the present disclosure; and

FIG. 7B is a cross-sectional view of an example semiconductor device fabricated using a dual damascene process that may be inspected using example embodiments described in the present disclosure.

Although similar reference numbers may be used to refer to similar elements for convenience, it can be appreciated that each of the various example embodiments may be considered to be distinct variations.

Example embodiments will now be described with reference to the accompanying drawings, which form a part of the present disclosure, and which illustrate example embodiments which may be practiced. As used in the present disclosure and the appended claims, the terms “example embodiment,” “exemplary embodiment,” and “present embodiment” do not necessarily refer to a single embodiment, although they may, and various example embodiments may be readily combined and/or interchanged without departing from the scope or spirit of example embodiments. Furthermore, the terminology as used in the present disclosure and the appended claims is for the purpose of describing example embodiments only and is not intended to be limitations. In this respect, as used in the present disclosure and the appended claims, the term “in” may include “in” and “on,” and the terms “a,” “an” and “the” may include singular and plural references. Furthermore, as used in the present disclosure and the appended claims, the term “by” may also mean “from,” depending on the context. Furthermore, as used in the present disclosure and the appended claims, the term “if” may also mean “when” or “upon,” depending on the context. Furthermore, as used in the present disclosure and the appended claims, the words “and/or” may refer to and encompass any and all possible combinations of one or more of the associated listed items.

### DETAILED DESCRIPTION

It is recognized in the present disclosure that recent developments in the fabrication of semiconductor structures and devices, including those using a damascene process, dual damascene process, or the like, have replaced traditional metals, such as aluminum, or the like, with other conductive materials, such as copper, or the like, when forming the conductive layers, including electrical interconnects, of the semiconductor device. One or more problems, however, are encountered in the fabrication of semiconductor structures and devices, including difficulties in achieving improved performance and increased reliability resulting from, among other things, defects arising on and within the conductive layer (electrical interconnects). Although defects on the surface (surface defects) of semiconductor structures and devices may be readily inspected, current methods and devices have not been effective in inspecting internal defects. Defects include surface inconsistencies and holes, pits, oxide bridges, partial breaks, and complete or total breaks (openings) in the conductive layer.

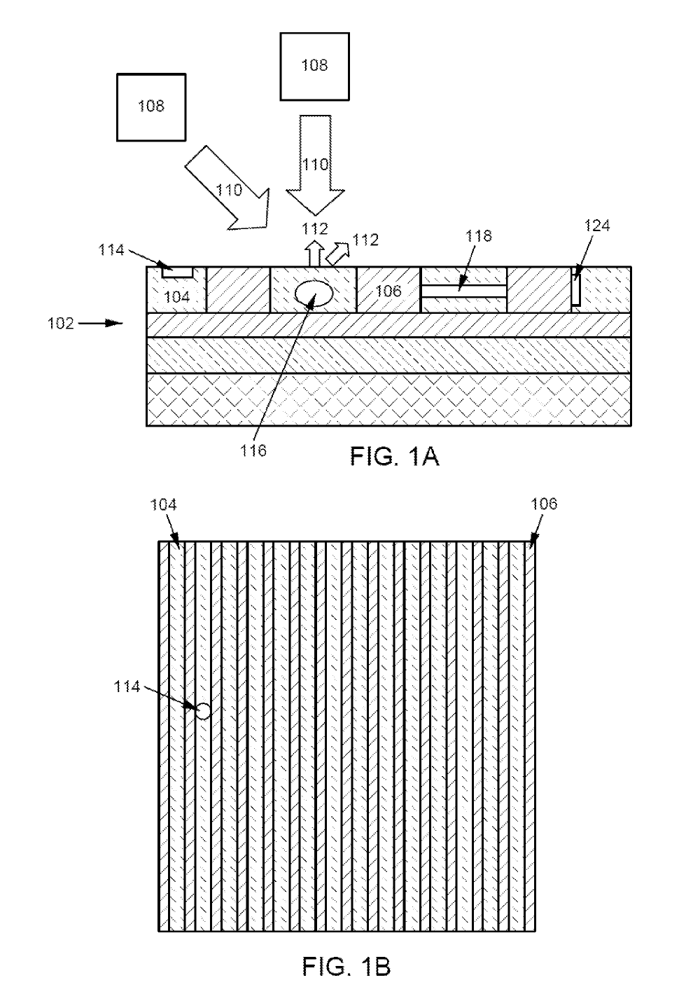

As illustrated in FIGS. 1A and 1B, surface inconsistencies (or defects) 114 in fabricated or partially fabricated semiconductor structures and devices, such as semiconductor structures 102 comprising a series of elongated conductive layers (or electrical interconnects) 104 separated by insulating walls 106, have conventionally been inspected using various optics-based inspection tools, such as inspection tools made by KLA-Tencor and other manufacturers 108. It is recognized in the present disclosure that such conventional optics-based methods and devices 108, however, suffer severe limitations in that, being optical inspection methods, they cannot generally detect interior defects of semiconductor structures and devices. In operation, such conventional methods and tools 108 operate by applying incident light 110 to a surface and measuring the light reflected and/or scattered back 112 from the surface. In other words and by way of example, while such conventional methods and tools 108 may confirm the presence of surface defects 114 of a conductive layer 104, it is recognized in the present disclosure that such conventional methods and tools 108 are not effective in determining the presence or existence of inconsistencies, including defects, within and/or at the conductor/oxide borders of the conductive layer 104.

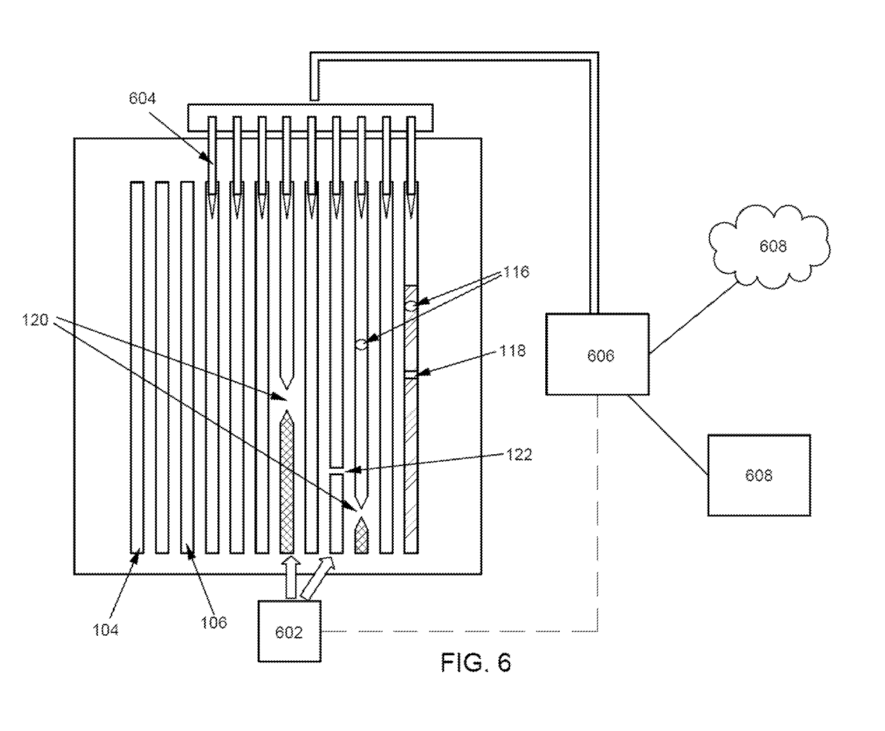

As illustrated in FIGS. 1A and 1B, as well as in FIG. 6, internal defects can include pits (or holes or cavities or bores) 116, partial breaks 118, complete breaks (or openings) 120, oxide bridges (which may include pits, partial breaks, and/or complete breaks filled or partially filled with insulating material from the insulating layer(s) 106) 122, and inconsistencies at the border 126 between the conductive layer 104 and the insulating layer 106.

Present example embodiments relate generally to methods, logic, systems, and devices for inspecting (or examining or testing) fabricated and/or partially fabricated semiconductor structures and/or devices. The use of the described example embodiments enable testers/inspectors to, among other things, improve the performance of their products and ensure their products are reliable and meet their product specifications. Example embodiments enable testers/inspectors to achieve this by determining if conductive layers of their semiconductor device comprise any internal defects and/or surface inconsistencies and/or defects. If internal defects are found, example embodiments also enable testers/inspectors to make a decision on whether or not to accept or reject the product during the inspection phase by determining the severity of the internal defects. Example embodiments also enable testers/inspectors to determine an approximate location of the internal defects within the conductive layer of fabricated and/or partially fabricated semiconductor structures and/or devices.

### (1) Identifying the Conductive Layer (e.g., Action 200)

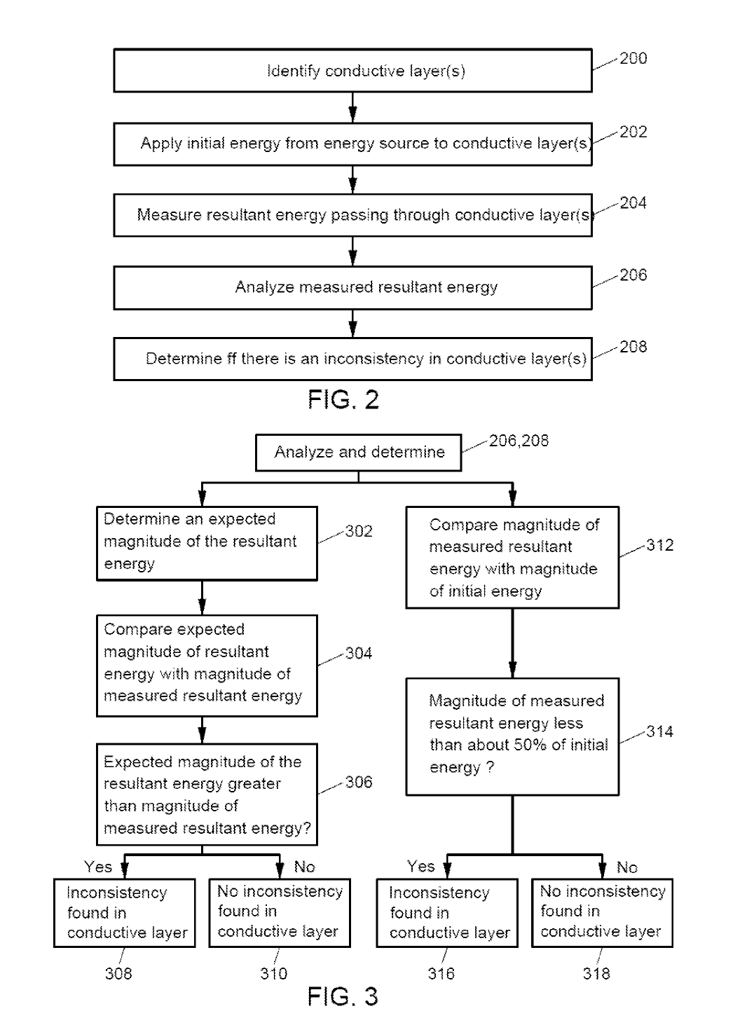

As illustrated in the sequence of actions of FIG. 2, methods may include identifying or locating one or more conductive layers 104 of the semiconductor device, which due to the continuously shrinking critical dimension requirements and demands in the semiconductor industry, may not be easily visible or identifiable through routine inspection (such as via the naked eye). For example, a low current may be applied by an energy source 602, such as an e-beam, to a location on a surface of the semiconductor device and a probe 604 may be applied to determine whether the location is a conductive layer 104 or an insulating (or oxide) layer 106.

### (2) Applying an Initial Energy (e.g., Action 202)

An initial energy (such as an electric current) may be applied from an energy source 602 to the identified conductive layer 104 of the semiconductor device. For example, an e-beam device 602 may apply electrical current to a first location (such as a first end) of the conductive layer 104.

### (3) Measuring a Resultant Energy Passing Through the Conductive Layer (e.g., Action 204)

After applying the initial energy from the energy source 602, a resultant energy (such as an electric current) may pass through the conductive layer 104. In an example embodiment, a probe 604 of the processor 606 or an energy measuring device (not shown) may be applied to a second location (such as a second end) of the conductive layer 104 to measure the resultant energy passing through the conductive layer 104. For example, the energy source 602 may apply the initial energy in action 202 at a first end of the conductive layer 104 and the probe 604 may be applied to measure the resulting energy at a second end of the conductive layer 104.

As illustrated in FIG. 6, an example embodiment of the system 600 used to inspect semiconductor devices may comprise the energy source 602, one or more of the probes 604, and the processor 606. The system 600 may further comprise memory 608 for storing logic to carry out one or more of the actions described in the present disclosure, measurement results, which conductive layer and/or device has one or more inconsistencies, the severities of one or more inconsistencies, and the approximate location of one or more inconsistencies. The memory 608 may be any non-transitory computer readable medium, including local data storage devices (such as hard disk drives, flash drives, and/or ROM) and/or remote storage devices or systems (such as network storage devices or the like and/or storage using cloud computing or the like).

The energy source 602 may be any energy source operable to apply the initial energy (or electric current) to one or more conductive layers 104. For example, the energy source 602 may include an e-beam generating device, an electric field generating device, a magnetic field generating device, a device that produces chemically induced energy, or the like.

The one or more probes 604 may be small enough to contact only a single conductive layer 104. The one or more probes 604 may be a needle probe and may comprise a conductive contact surface at one end. The conductive contact surface may comprise a dimension lesser than about 0.1 microns, and may comprise carbon, carbon nanotube, metal, graphite, or other conductive materials. Furthermore, the one or more probes 604 may be flexible in structure so as to prevent being damaged when being applied to a conductive layer 104. In example embodiments, the probes 604 may also be non-flexible.

The processor 606, and/or logic storable in the memory 608 and executable by the processor 606, may be operable to perform one or more of the operations or actions provided above and in the present disclosure, including, but not limited to, one or more of: controlling of and/or receiving raw information from the probes representing the measured resultant energy passing through the conductive layer 104 and/or converting the information into measured resultant energy; analyzing the magnitude of the measured resultant energy passing through one or more conductive layers 104, including comparing the magnitude of the measured resultant energy with an expected magnitude of the resultant energy and/or the magnitude of the initial energy; determining a presence (or absence) of one or more inconsistencies in the conductive layer 104; moving (or sliding or scanning), either continuously, intermittently, periodically, or on-demand, the application of the initial energy from a first location on the conductive layer 104 that already received the initial energy to a new (or adjacent) location towards the location that is measuring the resulting energy (such as the location of the probe 604) while also measuring/monitoring the resulting energy passing through the conductive layer 104; moving (or sliding or scanning), either continuously, intermittently, periodically, or on-demand, the probe 604 from a first location on the conductive layer 104 that already measured the resultant energy passing through the conductive layer 104 to a new (or adjacent) location towards the location on the conductive layer 104 that is receiving the application of the initial energy while also measuring/monitoring the resulting energy passing through the conductive layer 104; repeat the previously described actions; identifying a severity of one or more inconsistencies in the conductive layer 104; and identifying a approximate location of one or more inconsistencies in the conductive layer 104. The processor 606 may be operable to control and/or communicate with and/or on behalf of the probes 604, the energy source 602, and/or the memory 608.

### (4) Analyzing the MEASURED RESULTANT ENERGY and Determining a Presence of an Inconsistency in the Conductive Layer (e.g., Actions 206 and 208)

As illustrated in FIG. 3, upon measuring the resultant energy passing through the conductive layer 104, the measured resultant energy may be analyzed by processor 606. In an example embodiment, the analysis may comprise action 302 of establishing an expected magnitude of the resultant energy. The expected magnitude of the resultant energy may be determinable in many ways, including applying the initial energy to, for example a known test system (not shown) having substantially the same conductive layer that does not have any inconsistencies or defects, and measuring the resultant energy passing through the test system. Upon establishing the expected magnitude of the resultant energy (action 302), the analysis by the processor 606 may proceed to action 304 of comparing the magnitude of the measured resultant energy with the expected magnitude of the resultant energy. As depicted in action 306, the processor 606 may then determine whether or not there is an inconsistency in the conductive layer 104. An inconsistency in the conductive layer 104 may be determined by the processor 606, as depicted in action 308, when the magnitude of the measured resultant energy is lesser than the expected magnitude of the resultant energy. On the other hand, the analysis by the processor 606 may determine that there are no inconsistencies in the conductive layer 104, as depicted in action 310, when the magnitude of the measured resultant energy is about the same as the expected magnitude of the resultant energy.

In an example embodiment, the analysis by the processor 606 may comprise comparing a magnitude of the measured resultant energy with a magnitude of the initial energy, as depicted in action 312. After a result of the comparing 314 is determined by the processor 606, the processor 606 may determine whether or not there is an inconsistency in the conductive layer 104. An inconsistency in the conductive layer 104 may be determined by the processor 606, as depicted in action 316, when the magnitude of the measured resultant energy is considerably less than the magnitude of the initial energy (i.e. there is an inconsistency in the conductive layer 104). In example embodiments, an inconsistency in the conductive layer 104 may be determined (action 316) by the processor 606 when the magnitude of the measured resultant energy is lesser than about 70% of the magnitude of the initial energy. On the other hand, the processor 606 may determine that there are no inconsistencies in the conductive layer 104, as depicted in action 318, when the magnitude of the measured resultant energy is not considerably less than the expected magnitude of the resultant energy. In example embodiments, an inconsistency in the conductive layer 104 may not be determinable and/or found (action 318) by the processor 606 when the magnitude of the measured resultant energy is greater than about 70% of the magnitude of the initial energy. One or more of the previously described actions may be performable by the processor 606 in example embodiments.

### (5) Identifying a Severity of the Inconsistency in the Conductive Layer (e.g., Action 404)

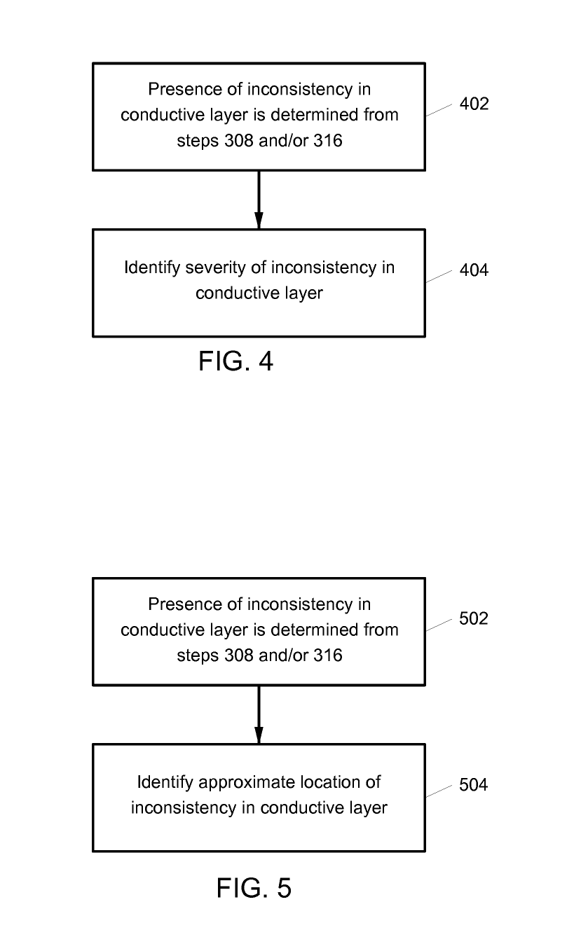

As illustrated in FIG. 4, upon the processor 606 determining that there is an inconsistency present in the conductive layer 104, an example embodiment may identify the severity of the inconsistency. The severity of the inconsistency may include a pit 116, an oxide bridge 122, a partial break 118, a complete break (or open) 120, and inconsistencies at the border 124 between the conductive layer 104 and the insulating layer 106. In an example embodiment, an expected magnitude of the resultant energy may be determined. In situations wherein the expected magnitude of the resultant energy cannot be readily determined (such as in situations wherein a test system is not available), the magnitude of the initial energy may be used in replacement of the expected magnitude of the resultant energy. The severity of the inconsistency may be identifiable, such as by the processor 606, as a pit 116 within the conductive layer 104 when a magnitude of the measured resultant energy is about 60-70% of the expected magnitude of the resultant energy (or the initial energy). The severity of the inconsistency may be identifiable, such as by the processor 606, as a partial break 118 within the conductive layer 104 when a magnitude of the measured resultant energy is lesser than about 60% of the expected magnitude of the resultant energy (or the initial energy), or more specifically, greater than about 0% and lesser than about 60%. The severity of the inconsistency may be identifiable, such as by the processor 606, as an oxide bridge 122 within the conductive layer 104 when a magnitude of the measured is resultant energy is about 0-10% of the expected magnitude of the resultant energy (or the initial energy). The severity of the inconsistency may be identifiable, such as by the processor 606, as a complete break (or opening) 120 of the conductive layer 104 when a magnitude of the measured resultant energy is about 0% of the expected magnitude of the resultant energy (or the initial energy). One or more of the previously described actions may be performable by the processor 606 in example embodiments.

### (6) Identifying an Approximate Location of the Inconsistency in the Conductive Layer (e.g., Action 504)

As illustrated in FIG. 5, upon determining that there is an inconsistency present in the conductive layer 104, an example embodiment may identify a approximate location of the inconsistency in the conductive layer 104, such as through use of the processor 606. It is to be understood in the present disclosure that action 504 of identifying an approximate location of the inconsistency in the conductive layer 104 may be performable before or after action 404 of identifying the severity of the inconsistency in the conductive layer 104, and may also be performable in replacement of action 402 in example embodiments. It is also to be understood that action 504 and/or action 404 and/or action 402 may be performed in example embodiments.

In an example embodiment, an approximate location of the inconsistency in the conductive layer 104 may be identified by moving (or sliding or scanning), either continuously, intermittently, periodically, and/or on-demand, either manually by a user or through instructions from the processor 606, the application of the initial energy from a location on the conductive layer 104 that previously received the initial energy towards the location that is measuring the resultant energy (i.e. the location of the probe 604) while also measuring/monitoring the resultant energy passing through the conductive layer 104. For example, when the energy source 602 applies the initial energy at a first location (such as a first end) of the conductive layer 104 and the probe 604 measuring the resulting energy is at a second location (such as a second end) of the conductive layer 104, the presence of an inconsistency in the conductive layer 104 may be determined by the processor 606. However, the approximate location of the inconsistency in the conductive layer 104 may not yet be known.

If the location where the initial energy is applied is moved slightly (or adjacently) towards the direction of the probe 602 and the measurement result still indicates that the magnitude of the measured resultant energy at this new location is about the same as the magnitude of the resultant energy measured prior to the move, then the approximate location of the inconsistency in the conductive layer 104 may still not yet be known for certain.

The previously described process may then be repeated (slightly moving the location to an adjacent location towards the direction of the probe 604 and applying the initial energy) until reaching an n+1^{th} location where the magnitude of the measured resultant energy is found to be greater than the magnitude of the measured resultant energy at a previous n^{th} location (location prior to the most recent moving). At this point, the approximate location of the inconsistency may then be determined, such as by the processor 606, to be either the n^{th} location (before the previous move) or between the previous n^{th} location and the present n+1^{th} location. Similarly, at this point, the severity of the inconsistency may also be determined, such as by the processor 606, based on the previous and/or present measured resultant energy measurements. It is to be understood in the present disclosure that example embodiments may also move (or slide or scan) the location of one or more of the probes 604 in addition to or in replacement of moving (or sliding or scanning) the location where the initial energy is applied (as described above). In doing so, the actions of determining the presence of the inconsistency, identifying the severity of the inconsistency, and identifying the approximate location of the inconsistency may be performable in substantially the same manner as that described above and in the present disclosure. These actions may be performable by the processor 606.

If the previously described measured magnitude of the resultant energy at the present n+1^{th} location, which is greater than the previously measured magnitude of the resultant energy at the previous n^{th} location, is still substantially less than the expected magnitude of the resultant energy (or the initial energy), then one or more other inconsistencies in the conductive layer 104 may exist between the present n+1^{th} location and the location of the probe 604. The aforementioned processes may then be repeated, such as by the processor 606, in substantially the same manner to locate (and/or identify the severity) the one or more other inconsistencies between the present n+1^{th} location and the probe 604. Similarly, previously described processes may also be repeated, such as by the processor 606, in substantially the same manner to identify the severity of the one or more other inconsistencies between the present n+1^{th} location and the probe 604. One or more of the aforementioned actions may be performable by the processor 606 in example embodiments. It is to be understood in the present disclosure that example embodiments may also move (or slide or scan) the location of one or more of the probes 604 in addition to or in replacement of moving (or sliding or scanning) the location where the initial energy is applied (as described above). Such actions may be performable by the processor 606. In doing so, the actions of identifying the severity of the one or more other inconsistencies and identifying the approximate location of the one or more other inconsistencies may be performable, such as by the processor 606, in substantially the same manner as that described above and in the present disclosure.

Example embodiments of the methods, logic, devices, and systems described in this description may simultaneously perform the inspection of one, some, or all conductive layers 104 in a series of conductive layers 104 (such as a series of parallel conductive layers 104). For example, a series of 32-64 probes 604 may be applied to measure the resultant energy for a corresponding series of 32-64 parallel conductive layers 104. It is to be understood that the number of probes 604 and the number of conductive layers 104 may be more than 64 or less than 32 in example embodiments, and the number of probes 604 may or may not be the same as the number of conductive layers 104 being inspected. It is also to be understood in the present disclosure that example embodiments are operable to detect more than one internal defect and more than one severity of internal defect within a conductive layer 104.

Example embodiments may also be operable to report, such as by the processor 606, the results of the inspection, including determining the presence of inconsistencies, identifying the severity of the inconsistencies, and identifying an approximate location of the inconsistencies. Such reporting may include sending the results of the inspection for displaying on a graphical display (not shown), sending the results of the inspection via electronic communications (such as via e-mail and/or other ways) to responsible personnel, databases, and/or other systems, and/or sending the results of the inspection for printing the results. The previously described action of sending the results of the inspection may be performable via communications, either directly through wired and/or wireless communication or indirectly, from the processor 606. Example embodiments may also be operable to provide, such as by the processor 606, results of the inspection for one or more manual and/or automatic adjustments to the fabrication process so as to prevent future occurrences of inconsistencies.

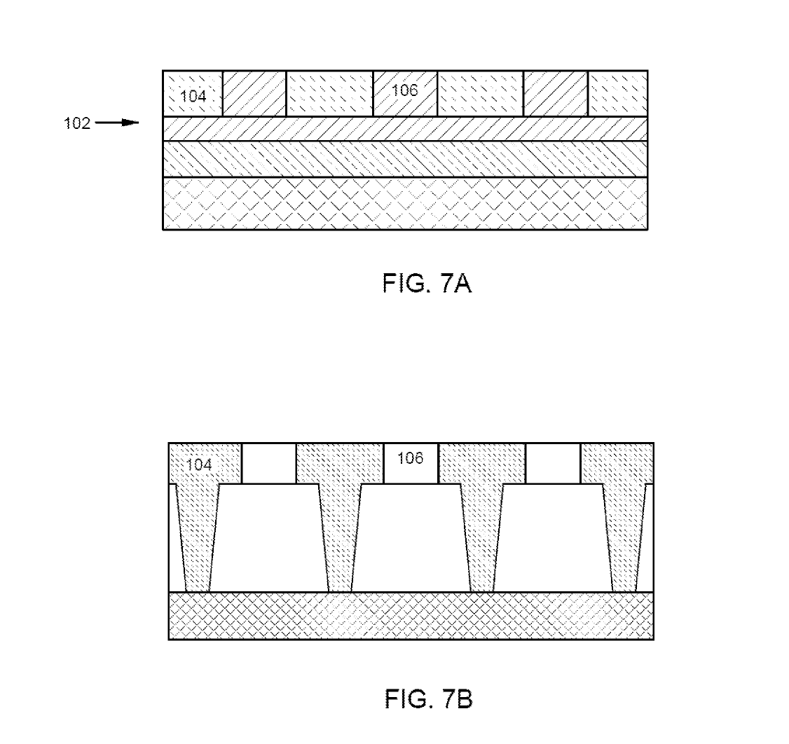

Although the example embodiments described above and in the present disclosure are generally described for inspecting semiconductor devices, example embodiments will be equally applicable to inspecting fabricated and/or partially fabricated semiconductor structures and/or devices, or the like. Furthermore, semiconductor devices fabricated using a damascene process, such as the cross-sectional view depicted in FIG. 7A, a dual damascene process, such as the cross-sectional view depicted in FIG. 7B, and other processes, are also contemplated in example embodiments.

While various embodiments in accordance with the disclosed principles have been described above, it should be understood that they have been presented by way of example only, and are not limiting. Thus, the breadth and scope of the example embodiments described in the present disclosure should not be limited by any of the above-described exemplary embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Various terms used in the present disclosure have special meanings within the present technical field. Whether a particular term should be construed as such a “term of art” depends on the context in which that term is used. “Connected to,” “in communication with,” “associated with,” or other similar terms should generally be construed broadly to include situations both where communications and connections are direct between referenced elements or through one or more intermediaries between the referenced elements. These and other terms are to be construed in light of the context in which they are used in the present disclosure and as one of ordinary skill in the art would understand those terms in the disclosed context. The above definitions are not exclusive of other meanings that might be imparted to those terms based on the disclosed context.

Words of comparison, measurement, and timing such as “at the time,” “equivalent,” “during,” “complete,” and the like should be understood to mean “substantially at the time,” “substantially equivalent,” “substantially during,” “substantially complete,” etc., where “substantially” means that such comparisons, measurements, and timings are practicable to accomplish the implicitly or expressly stated desired result.

Additionally, the section headings in the present disclosure are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings in the present disclosure.

What is claimed is:

1. A method of inspecting a semiconductor device, the method comprising:
applying an initial energy from an energy source to a first location of a conductive layer of the semiconductor device;
measuring a resultant energy passing through the conductive layer using a probe applied at a second location of the conductive layer;
analyzing the measured resultant energy passing through the conductive layer; and
determining a presence of an inconsistency in the conductive layer based on the analyzing.

2. The method of claim 1, wherein the analyzing comprises comparing a magnitude of the measured resultant energy with a magnitude of the initial energy, and wherein the presence of the inconsistency is determined when the magnitude of the measured resultant energy is less than about 50% of the magnitude of the initial energy.

3. The method of claim 1, wherein the analyzing comprises establishing an expected magnitude of the resultant energy based on a magnitude of the initial energy and comparing a magnitude of the measured resultant energy with the expected magnitude of the resultant energy, and wherein the presence of the inconsistency is determined when the magnitude of the measured resultant energy is less than the expected magnitude of the resultant energy.

4. The method of claim 1, further comprising identifying a severity of the inconsistency.

5. The method of claim 6, wherein the severity of the inconsistency is identifiable as a pit within the conductive layer when a magnitude of the measured resultant energy is about 60-70% of an expected magnitude of the resultant energy.

6. The method of claim 6, wherein the severity of the inconsistency is identifiable as a partial break within the conductive layer when a magnitude of the measured resultant energy is less than about 50% of an expected magnitude of the resultant energy.

7. The method of claim 6, wherein the severity of the inconsistency is identifiable as an oxide bridge within the conductive layer when a magnitude of the measured resultant energy is about 0-10% of an expected magnitude of the resultant energy.

8. The method of claim 6, wherein the severity of the inconsistency is identifiable as a complete break of the conductive layer when a magnitude of the measured resultant energy is about 0% of an expected magnitude of the resultant energy.

9. The method of claim 2, further comprising identifying a approximate location of the inconsistency in the conductive layer by:
applying the initial energy at a third location of the conductive layer, the third location being adjacent to the first location;
measuring a second resultant energy passing through the conductive layer between the third location and the probe; and
identifying the first location to be the location of the inconsistency in the conductive layer when a magnitude of the measured second resultant energy is greater than a magnitude of the measured resultant energy.

10. The method of claim 1, wherein the conductive layer being inspected is an elongated copper layer formed using a damascene or a dual damascene process.

11. A system for inspecting a semiconductor device, the system comprising:
an energy source operable to apply an initial energy to a first location of a conductive layer of the semiconductor device;
a probe operable to measure a resultant energy passing through the conductive layer at a second location of the conductive layer; and
a processor operable to:
analyze the measured resultant energy passing through the conductive layer; and
determine a presence of an inconsistency in the conductive layer based on the analyzing.

12. The system of claim 11, wherein a tip of the probe comprises a conductive contact surface operable to be applied at the second location, the conductive contact surface having a dimension of lesser than about 0.1 microns.

13. The system of claim 11, wherein the processor analyzes by comparing a magnitude of the measured resultant energy with a magnitude of the initial energy, and wherein the processor determines the presence of the inconsistency when the magnitude of the measured resultant energy is less than about 50% of the magnitude of the initial energy.

14. The system of claim 11, wherein the processor analyzes by establishing an expected magnitude of the resultant energy based on a magnitude of the initial energy and comparing a magnitude of the measured resultant energy with the expected magnitude of the resultant energy, and wherein the processor determines the presence of the inconsistency when the magnitude of the measured resultant energy is less than the expected magnitude of the resultant energy.

15. The system of claim 11, wherein the processor is further operable to identify a severity of the inconsistency.

16. The system of claim 15, wherein the processor is operable to identify the severity of the inconsistency as a pit within the conductive layer when a magnitude of the measured resultant energy is about 60-70% of an expected magnitude of the resultant energy.

17. The system of claim 15, wherein the processor is operable to identify the severity of the inconsistency as a partial break within the conductive layer when a magnitude of the measured resultant energy is less than about 50% of an expected magnitude of the resultant energy.

18. The system of claim 15, wherein the processor is operable to identify the severity of the inconsistency as an oxide bridge within the conductive layer when a magnitude of the measured resultant energy is about 0-10% of an expected magnitude of the resultant energy.

19. The system of claim 15, wherein the processor is operable to identify the severity of the inconsistency as a complete break of the conductive layer when a magnitude of the measured resultant energy is about 0% of an expected magnitude of the resultant energy.

20. The system of claim 11, wherein:
the energy source is further operable to apply the initial energy at a third location of the conductive layer, the third location being adjacent to the first location;
the probe is further operable to measure a second resultant energy passing through the conductive layer between the third location and the probe; and
the processor is further operable to identify the first location to be a approximate location of the inconsistency in the conductive layer when a magnitude of the measured second resultant energy is greater than a magnitude of the measured resultant energy.

21. The system of claim 11, wherein the conductive layer being inspected is an elongated copper layer formed using a damascene or a dual damascene process.
